(19) United States
(12) Patent Application Publication
(10) Pub. No.: US 2020/0083320 A1
(43) Pub. Date: Mar. 12, 2020

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Hiroshi Ohta, Kanazawa Ishikawa (JP); Syotaro Ono, Kanazawa Ishikawa (JP); Hideto Sugawara, Nonoichi Ishikawa (JP); Hisao Ichijo, Kanazawa Ishikawa (JP); Hiroaki Yamashita, Hakusan Ishikawa (JP)

(73) Assignees: Kabushiki Kaisha Toshiba, Tokyo (JP); Toshiba Electronic Devices & Storage Corporation, Tokyo (JP)

(21) Appl. No.: 16/285,685

(22) Filed: Feb. 26, 2019

(30) Foreign Application Priority Data
Sep. 6, 2018 (JP) 2018-166783

(51) Int. Cl. H01L 29/06; H01L 29/78; H01L 29/10

(52) U.S. Cl. CPC H01L 29/0634; H01L 29/1095; H01L 29/7827

(57) ABSTRACT

A semiconductor device includes a semiconductor body including a first semiconductor layer of a first conductivity type and a second semiconductor layer of a second conductivity type. The first and second semiconductor layers are alternately arranged in a first direction along a front surface of the semiconductor body, and each include multiple portions arranged in a second direction directed from a back surface toward the front surface of the semiconductor body. The first and second semiconductor layers are configured such that, in an active region, a large/small relationship between amounts of the first conductivity type impurity and the second conductivity type impurity in the portions positioned at the same level in the second direction reverses at a center in the second direction of the second semiconductor layer, and in the terminal region, the large/small relationship reverses alternately in the portions arranged in the second direction.

### CROSS-REFERENCE TO RELATED APPLICATIONS

This application is based upon and claims the benefit of priority from Japanese Patent Application No. 2018-166783, filed on Sep. 6, 2018; the entire contents of which are incorporated herein by reference.

### FIELD

Embodiments relate to a semiconductor device.

### BACKGROUND

A semiconductor device used for power control may have a so-called super junction structure in which n-type semiconductor layers and p-type semiconductor layers are arranged alternately along a direction crossing the flowing direction of current. It is possible in the semiconductor device using the super junction structure to achieve a high breakdown voltage and low ON-resistance, but the avalanche resistance may degrade at the terminal portion thereof.

### BRIEF DESCRIPTION OF THE DRAWINGS

FIGS. 1A and 1B are schematic views showing a semiconductor device according to an embodiment;

FIGS. 2A to 2C are schematic views showing the active region of the semiconductor device according to the embodiment;

FIGS. 3A to 3C are schematic views showing the terminal region of the semiconductor device according to the embodiment;

FIGS. 4A and 4B are schematic views showing the impurity concentration profiles and the electric field distribution of the terminal region according to a modification of the embodiment; and

FIG. 5A to FIG. 6B are schematic cross-sectional views showing manufacturing processes of the semiconductor device according to the embodiment.

### DETAILED DESCRIPTION

According to one embodiment, a semiconductor device includes a semiconductor body, a first electrode provided on a front surface of the semiconductor body, a second electrode provided on a back surface of the semiconductor body, and a control electrode provided between the semiconductor body and the first electrode; and the semiconductor body includes a first semiconductor layer of a first conductivity type and a second semiconductor layer of a second conductivity type. The first semiconductor layer and the second semiconductor layer are arranged alternately in a first direction; and the first direction is along the front surface of the semiconductor body. The semiconductor body includes an active region and a terminal region; the active region includes a third semiconductor layer of the second conductivity type and a fourth semiconductor layer of a first conductivity type; the third semiconductor layer is provided between the second semiconductor layer and the first electrode; the fourth semiconductor layer is provided between the third semiconductor layer and the first electrode; and the terminal region surrounds the active region and is positioned in a direction along the front surface when viewed from the active region. The third semiconductor layer and the fourth semiconductor layer are not provided in the terminal region; the first semiconductor layer includes a first portion, a second portion, a third portion, and a fourth portion arranged in a second direction from the back surface toward the front surface of the semiconductor body; the second semiconductor layer includes a fifth portion, a sixth portion, a seventh portion, and an eighth portion arranged in the second direction from the back surface toward the front surface of the semiconductor body; the first portion is positioned at the same level as the fifth portion in the second direction; the second portion is positioned at the same level as the sixth portion in the second direction; the third portion is positioned at the same level as the seventh portion in the second direction; and the fourth portion is positioned at the same level as the eighth portion in the second direction. For the first semiconductor layer and the second semiconductor layer positioned in the active region, a second-conductivity-type impurity included in the fifth portion is less than a first-conductivity-type impurity of the first portion; the second-conductivity-type impurity included in the sixth portion is less than the first-conductivity-type impurity of the second portion; the second-conductivity-type impurity included in the seventh portion is more than the first-conductivity-type impurity of the third portion; and the second-conductivity-type impurity included in the eighth portion is more than the first-conductivity-type impurity of the fourth portion. For the first semiconductor layer and the second semiconductor layer positioned in the terminal region, the second-conductivity-type impurity included in the fifth portion is less than the first-conductivity-type impurity of the first portion; the second-conductivity-type impurity included in the sixth portion is more than the first-conductivity-type impurity of the second portion; and the second-conductivity-type impurity included in the seventh portion is less than the first-conductivity-type impurity of the third portion; and the second-conductivity-type impurity included in the eighth portion is more than the first-conductivity-type impurity of the fourth portion. For the first semiconductor layer and the second semiconductor layer positioned in the terminal region, a total amount of the first-conductivity-type impurity in the first portion and the second portion is less than a total amount of the first-conductivity-type impurity in the third portion and the fourth portion.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

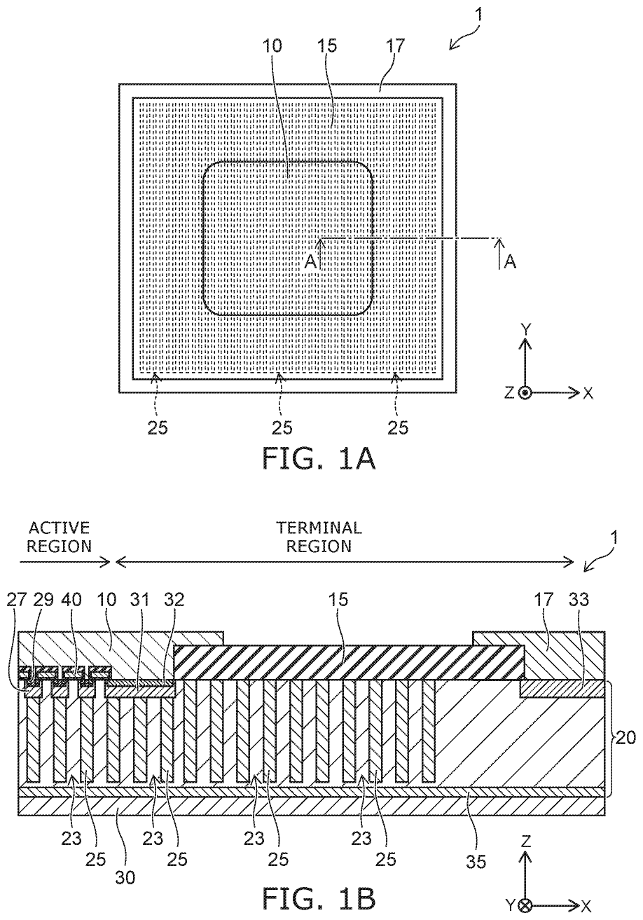

FIGS. 1A and 1B are schematic views showing a semiconductor device 1 according to an embodiment. The semiconductor device 1 is, for example, a power MOSFET. FIG. 1A is a schematic view illustrating the upper surface of the semiconductor device 1. FIG. 1B is a schematic view showing a cross section along line A-A shown in FIG. 1A.

As shown in FIG. 1A, the semiconductor device 1 includes a source electrode 10, a dielectric film 15, an EQPR electrode 17 (Equivalent Potential Ring electrode), and a semiconductor body 20 (referring to FIG. 1B). The source electrode 10 is provided on an active region of the semiconductor body 20. The dielectric film 15 and the EQPR electrode 17 are provided on a terminal region surrounding the active region of the semiconductor body 20.

As shown in FIG. 1B, the semiconductor device 1 further includes a drain electrode 30 and a gate electrode 40. The source electrode 10, the dielectric film 15, and the EQPR electrode 17 are provided on the front surface of the semiconductor body 20. The drain electrode 30 is provided on the back surface of the semiconductor body 20. The gate electrode 40 is provided between the source electrode 10 and the semiconductor body 20.

The semiconductor body 20 includes an n-type semiconductor layer 23 and a p-type semiconductor layer 25. For example, the n-type semiconductor layer 23 and the p-type semiconductor layer 25 are provided in plate configurations extending in the Y-direction and the Z-direction. The n-type semiconductor layer 23 and the p-type semiconductor layer 25 are arranged alternately in the X-direction.

The semiconductor body 20 further includes a p-type diffusion layer 27, an n-type source layer 29, a p-type diffusion layer 31, a p-type contact layer 32, a p-type channel stopper layer 33, and an n-type drain layer 35.

The p-type diffusion layer 27 and the n-type source layer 29 are provided in the active region. The p-type diffusion layer 31 is provided at the boundary between the active region and the terminal region. The p-type channel stopper layer 33 is provided at the outermost perimeter portion of the semiconductor body 20 directly under the EQPR electrode 17 to surround the terminal region.

The p-type diffusion layer 31 is provided between the source electrode 10 and the n-type semiconductor layer 23 and between the source electrode 10 and the p-type semiconductor layer 25. Also, the p-type diffusion layer 31 is provided to surround the active region. The p-type contact layer 32 is provided between the source electrode 10 and the p-type diffusion layer 31 and includes a p-type impurity having a higher concentration than a concentration of the p-type impurity in the p-type diffusion layer 31. The source electrode 10 has, for example, an ohmic contact with the p-type contact layer 32, and is electrically connected to the p-type diffusion layer 31.

The n-type drain layer 35 is disposed between the n-type semiconductor layer 23 and the drain electrode 30 and between the p-type semiconductor layer 25 and the drain electrode 30. The n-type drain layer 35 includes, for example, an n-type impurity having a higher concentration than a concentration of the n-type impurity in the n-type semiconductor layer 23. The drain electrode 30 has, for example, an ohmic contact with the n-type drain layer 35.

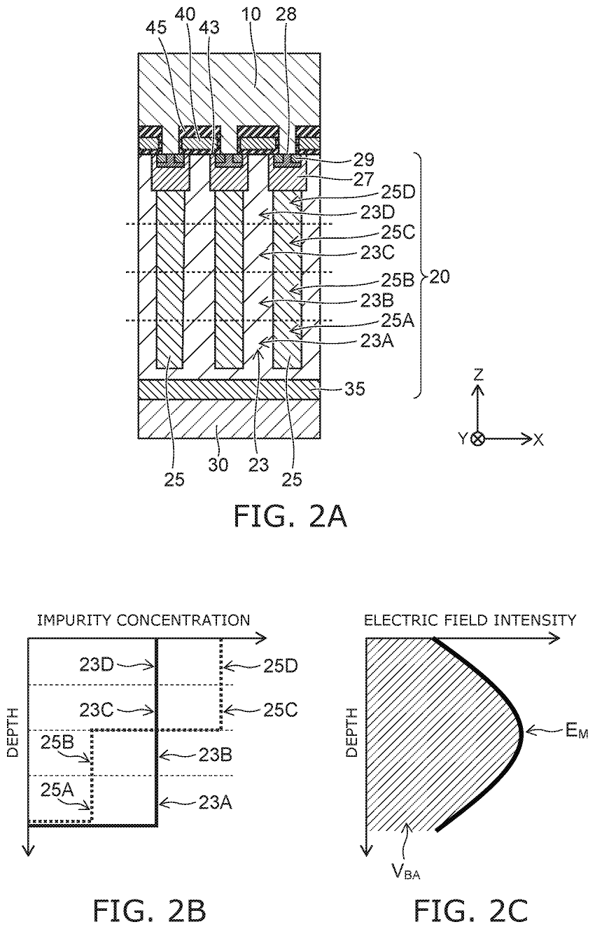

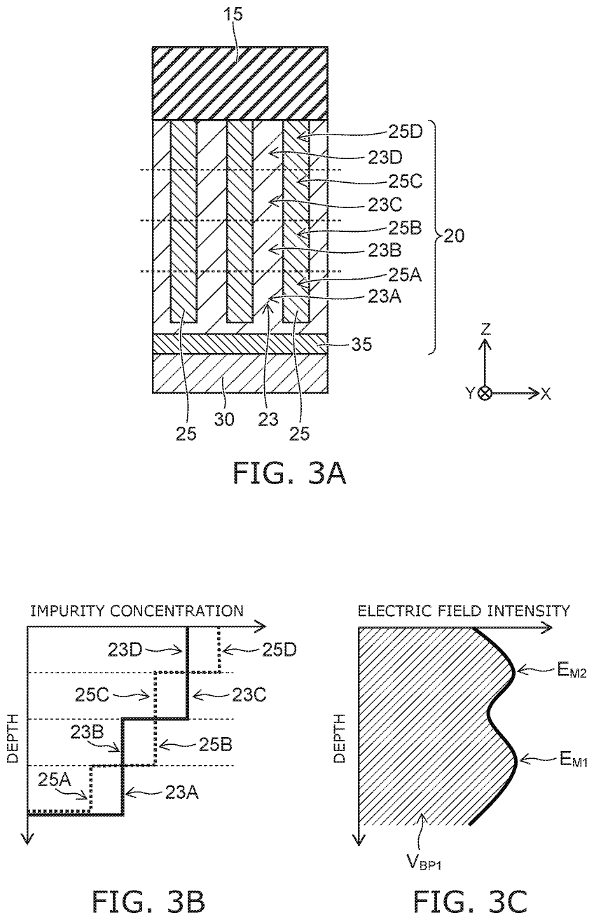

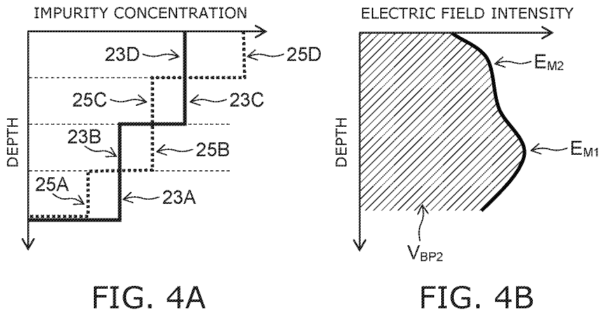

FIGS. 2A to 2C are schematic views showing the active region of the semiconductor device 1 according to the embodiment. FIG. 2A is a schematic view showing a cross section of the active region. FIG. 2B is a schematic view showing the impurity concentrations of the n-type semiconductor layer 23 and the p-type semiconductor layer 25 disposed in the active region. FIG. 2C is a schematic view showing the electric field distribution in the active region. The levels of the impurity concentrations shown in FIG. 2B correspond to the magnitude of the impurity amount included in each portion of the n-type semiconductor layer 23 and the p-type semiconductor layer 25. This is similar for FIG. 3B and FIG. 4A hereinbelow.

As shown in FIG. 2A, the p-type diffusion layer 27 is provided between the source electrode 10 and the p-type semiconductor layer 25. The n-type source layer 29 is selectively provided between the source electrode 10 and the p-type diffusion layer 27. Also, a p-type contact layer 28 is selectively provided between the source electrode 10 and the p-type diffusion layer 27. The p-type contact layer 28 includes a p-type impurity having a higher concentration than a concentration of the p-type impurity in the p-type diffusion layer 27. The p-type contact layer 28 and the n-type source layer 29 are arranged along the front surface of the semiconductor body 20.

For example, the gate electrodes 40 are disposed on the active region of the semiconductor body 20, and are arranged in the X-direction. For example, the gate electrode 40 is disposed to face, with a gate insulating film 43 interposed, the n-type semiconductor layer 23, the p-type diffusion layer 27 exposed between the n-type semiconductor layer 23 and the n-type source layer 29, and a portion of the n-type source layer 29 exposed at the front surface of the semiconductor body 20. The portion of the n-type source layer 29 is positioned adjacent to the p-type diffusion layer 27 that is positioned between the n-type semiconductor layer 23 and the n-type source layer 29.

The source electrode 10 is provided to contact the p-type contact layer 28 and the n-type source layer 29 between the gate electrodes 40. The source electrode 10 is electrically connected to the p-type diffusion layer 27 via the p-type contact layer 28. Also, the source electrode 10 is provided to cover the gate electrode 40; and the gate electrode 40 is electrically insulated from the source electrode 10 by an inter-layer insulating film 45.

For example, the n-type semiconductor layer 23 includes a first portion 23A, a second portion 23B, a third portion 23C, and a fourth portion 23D arranged in the Z-direction from the n-type drain layer 35 side. Also, the p-type semiconductor layer 25 includes, for example, a fifth portion 25A, a sixth portion 25B, a seventh portion 25C, and an eighth portion 25D arranged in the Z-direction from the n-type drain layer 35 side.

The first portion 23A is positioned at the same level as a level of the fifth portion 25A in the Z-direction. The second portion 23B is positioned at the same level as a level of the sixth portion 25B in the Z-direction. The third portion 23C is positioned at the same level as a level of the seventh portion 25C in the Z-direction. The fourth portion 23D is positioned at the same level as a level of the eighth portion 25D in the Z-direction.

As shown in FIG. 2B, for example, the n-type semiconductor layer 23 is provided so that the concentration of the n-type impurity is constant in the first to fourth portions 23A to 23D. On the other hand, for example, the p-type semiconductor layer 25 is provided so that the p-type impurity concentration of the fifth portion 25A is the same as the p-type impurity concentration of the sixth portion 25B, and the p-type impurity concentration of the seventh portion 25C is the same as the p-type impurity concentration of the eighth portion 25D. The p-type impurity concentrations of the seventh portion 25C and the eighth portion 25D are higher than the p-type impurity concentrations of the fifth portion 25A and the sixth portion 25B.

The p-type impurity concentration of the fifth portion 25A is lower than the n-type impurity concentration of the first portion 23A; and the p-type impurity concentration of the sixth portion 25B is lower than the n-type impurity concentration of the second portion 23B. The p-type impurity concentration of the seventh portion 25C is higher than the n-type impurity concentration of the third portion 23C; and the p-type impurity concentration of the eighth portion 25D is higher than the n-type impurity concentration of the fourth portion 23D.

For example, the n-type semiconductor layers 23 are arranged at uniform spacing in the X-direction. Moreover, the n-type semiconductor layers 23 arranged in the X-direction have a constant width in the X-direction, respectively. Also, the p-type semiconductor layers 25 each have a constant width in the X-direction. The total amount of the n-type impurity and the total amount of the p-type impurity are balanced in a region that includes an n-type semiconductor layer 23 and a p-type semiconductor layer 25 adjacent thereto. Here, “balanced” means that the total amount of the n-type impurity is substantially the same as the total amount of the p-type impurity. The total amount of the n-type impurity refers to the total amount of the n-type impurity included in the n-type semiconductor layer 23 and the background-level n-type impurity included in the p-type semiconductor layer 25. The total amount of the p-type impurity refers to the total amount of the p-type impurity included in the p-type semiconductor layer 25 and the background-level p-type impurity included in the n-type semiconductor layer 23.

FIG. 2C shows the electric field distribution of the active region in the OFF-state in which, for example, a reverse bias is applied between the source electrode 10 and the drain electrode 30 and a gate bias is not applied to the gate electrode 40. As shown in FIG. 2C, for example, the electric field of the active region has an electric field peak E_{M} at the center level in the Z-direction of the p-type semiconductor layer 25, and has a distribution decreasing in the directions toward the source electrode 10 and the drain electrode 30.

FIGS. 3A to 3C are schematic views showing the terminal region of the semiconductor device 1 according to the embodiment. FIG. 3A is a schematic view showing a cross section of the terminal region. FIG. 3B is a schematic view showing the impurity concentrations of the n-type semiconductor layer 23 and the p-type semiconductor layer 25 disposed in the terminal region. FIG. 3C is a schematic view showing the electric field distribution in the terminal region.

As shown in FIG. 3A, the n-type semiconductor layer 23 and the p-type semiconductor layer 25 that are disposed in the terminal region is provided to contact the dielectric film 15 at the upper ends of the n-type semiconductor layer 23 and the p-type semiconductor layer 25. The dielectric film 15 is, for example, a silicon oxide film.

The n-type semiconductor layer 23 includes, for example, the first portion 23A, the second portion 23B, the third portion 23C, and the fourth portion 23D arranged in the Z-direction from the n-type drain layer 35 side. The p-type semiconductor layer 25 includes, for example, the fifth portion 25A, the sixth portion 25B, the seventh portion 25C, and the eighth portion 25D arranged in the Z-direction from the n-type drain layer 35 side.

The first portion 23A is positioned at the same level as a level of the fifth portion 25A in the Z-direction. The second portion 23B is positioned at the same level as a level of the sixth portion 25B in the Z-direction. The third portion 23C is positioned at the same level as a level of the seventh portion 25C in the Z-direction. The fourth portion 23D is positioned at the same level as a level of the eighth portion 25D in the Z-direction.

As shown in FIG. 3B, for example, the n-type semiconductor layer 23 is provided so that the n-type impurity concentration of the first portion 23A is the same as the n-type impurity concentration of the second portion 23B, and the n-type impurity concentration of the third portion 23C is the same as the n-type impurity concentration of the fourth portion 23D. The n-type impurity concentrations of the third portion 23C and the fourth portion 23D are higher than the n-type impurity concentrations of the first portion 23A and the second portion 23B.

In the p-type semiconductor layer 25, the p-type impurity concentration of the fifth portion 25A is lower than the n-type impurity concentration of the first portion 23A; and the p-type impurity concentration of the sixth portion 25B is higher than the n-type impurity concentration of the second portion 23B. The p-type impurity concentration of the seventh portion 25C is lower than the n-type impurity concentration of the third portion 23C; and the p-type impurity concentration of the eighth portion 25D is higher than the n-type impurity concentration of the fourth portion 23D.

For example, the n-type semiconductor layers 23 are arranged at uniform spacing in the X-direction. Moreover, the n-type semiconductor layers 23 arranged in the X-direction have a constant width in the X-direction, respectively. Also, the p-type semiconductor layers 25 each have a constant width in the X-direction. The width in the X-direction is constant for the p-type semiconductor layers 25. The total amount of the n-type impurity and the total amount of the p-type impurity are balanced in a region that includes an n-type semiconductor layer 23 and a p-type semiconductor layer 25 adjacent thereto. Also, the total amount of the n-type impurity and the total amount of the p-type impurity are balanced in a region that includes the first portion 23A, the second portion 23B, the fifth portion 25A, and the sixth portion 25B. Further, the total amount of the n-type impurity and the total amount of the p-type impurity are balanced in other region that includes the third portion 23C, the fourth portion 23D, the seventh portion 25C, and the eighth portion 25D.

As shown in FIG. 3C, for example, the electric field distribution of the terminal region has a first peak E_{M1} at the level of the boundary between the fifth portion 25A and the sixth portion 25B and has a second peak E_{M2} at the level of the boundary between the seventh portion 25C and the eighth portion 25D. For example, a breakdown voltage V_{BP1} in the terminal region is higher than a breakdown voltage V_{BA} in the active region (referring to FIG. 2C). Here, the breakdown voltages V_{BA} and V_{BP1} are the integrated values in the depth direction of the electric field distributions shown in FIG. 2C and FIG. 3C.

For example, in the process of switching the semiconductor device 1 OFF, avalanche breakdown occurs and generates an avalanche current. The avalanche current that is generated in the active region flows to the source electrode 10 via the p-type diffusion layer 27 provided at the upper end of each of the p-type semiconductor layers 25. On the other hand, the n-type semiconductor layers 23 and the p-type semiconductor layers 25 that are disposed in the terminal region are provided to contact the dielectric film 15. Therefore, there are cases where the avalanche current generated in the terminal region concentrates and flows to the p-type diffusion layer 31 positioned at the boundary between the terminal region and the active region, and thus, reduces the avalanche resistance.

The n-type semiconductor layer 23 and the p-type semiconductor layer 25 of the embodiment are provided to have different concentration profiles between the active region and the terminal region. Therefore, the breakdown voltage V_{BP1} of the terminal region can be set to be higher than the breakdown voltage V_{BA} of the active region. Thereby, for the OFF-state, it is possible to set the electric field of the terminal region to be lower than the electric field of the active region; and the avalanche breakdown can be avoided to occur in the terminal region. In other words, the generation of the avalanche current can be avoided. As a result, in the semiconductor device 1, the decrease of the avalanche resistance caused by the terminal region can be avoided.

FIGS. 4A and 4B are schematic views showing the concentration profiles and the electric field distribution of the terminal region according to a modification of the embodiment. FIG. 4A is a schematic view showing the concentration profiles of the n-type semiconductor layer 23 and the p-type semiconductor layer 25. FIG. 4B is a schematic view showing the electric field distribution in the terminal region.

As shown in FIG. 4A, in this example, the concentration of the p-type impurity of the eighth portion 25D in the p-type semiconductor layer 25 is set to be higher than that of the example shown in FIG. 3B. Thereby, in the third portion 23C, the fourth portion 23D, the seventh portion 25C, and the eighth portion 25D, the total amount of the p-type impurity is more than the total amount of the n-type impurity.

In the electric field distribution shown in FIG. 4B, compared to the electric field distribution shown in FIG. 3C, the second peak E_{M2} is low, which is positioned at the level of the boundary between the seventh portion 25C and the eighth portion 25D. That is, the electric field at the front surface of the semiconductor body 20 in the terminal region decreases. In other words, the electric field at the front surface of the semiconductor body 20 can be reduced while maintaining a breakdown voltage V_{BP2} in the terminal region that is higher than the breakdown voltage V_{BA} in the active region.

Under the electric field distribution shown in FIG. 4B, it is possible to suppress the injection of hot carriers from the semiconductor body 20 into the dielectric film 15; and the interface state between the semiconductor body 20 and the dielectric film 15 can be stable. Thereby, the reliability of the semiconductor device 1 can be improved.

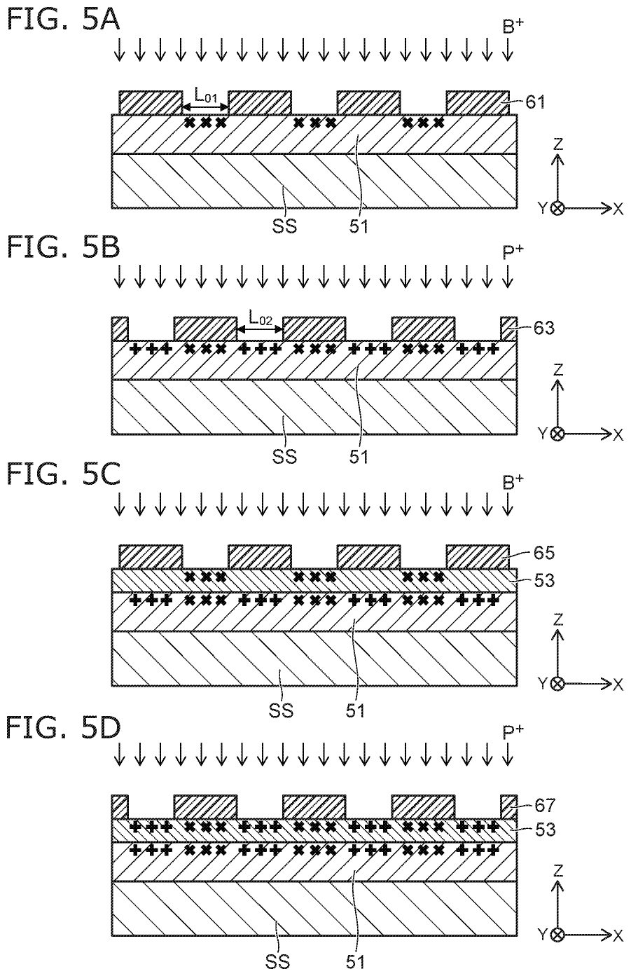

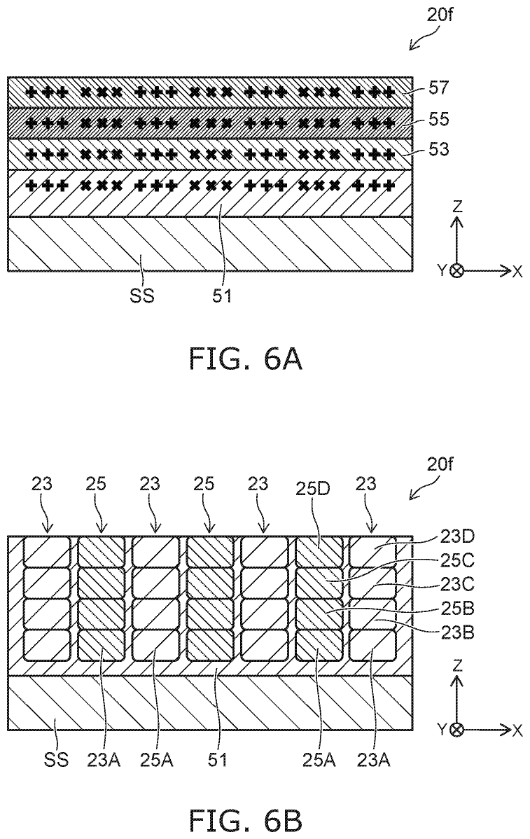

FIG. 5A to FIG. 6B are schematic cross-sectional views showing manufacturing processes of the semiconductor device 1 according to the embodiment. FIG. 5A to FIG. 6B are schematic views illustrating the processes for forming a super junction structure in which the n-type semiconductor layer 23 and the p-type semiconductor layer 25 are arranged alternately.

As shown in FIG. 5A, a semiconductor layer 51 is formed on a semiconductor substrate SS; subsequently, for example, boron (B) which is the p-type impurity is ion-implanted selectively. The semiconductor substrate SS is, for example, an n-type silicon substrate. The semiconductor layer 51 is, for example, a silicon layer and is epitaxially grown on the semiconductor substrate SS. For example, impurities are not intentionally added in the growth process of the semiconductor layer 51. The semiconductor layer 51 is a so-called undoped layer. The semiconductor layer 51 is, for example, an n-type silicon layer including an n-type impurity with a low concentration.

For example, ion implantation is performed selectively using an ion implantation mask 61. The ion implantation mask 61 has openings corresponding to the portions of the semiconductor layer 51 where the impurity is to be introduced. The impurity amount that is implanted into the semiconductor layer 51 can be controlled by the dose amount of the ion implantation and can be controlled by a width L₀₁ of the opening. For example, the ion implantation mask 61 is formed so that the width L₀₁ of the opening provided in the active region is different from the width L₀₁ of the opening provided in the terminal region. Thereby, in one ion implantation, the different amount of the p-type impurity from the p-type impurity amount in the active region can be introduced to the terminal region.

As shown in FIG. 5B, for example, phosphorus (P) which is the n-type impurity is ion-implanted selectively into the semiconductor layer 51. By using an ion implantation mask 63, the n-type impurity is introduced to portions where the p-type impurity is not ion-implanted. Also in such a case, it is possible to introduce an amount of the p-type impurity to the terminal region, which is different from the p-type impurity amount in the active region, by using the ion implantation mask 63 in which a width L₀₂ of the opening provided in the terminal region is different from the width L₀₂ of the opening provided in the active region.

As shown in FIG. 5C, an undoped semiconductor layer 53 is epitaxially grown on the semiconductor layer 51; subsequently, for example, boron which is the p-type impurity is ion-implanted selectively using an ion implantation mask 65. The portions of the semiconductor layer 53 where the p-type impurity is introduced are positioned directly above the portions of the semiconductor layer 51 where the p-type impurity is introduced. The p-type impurity amount that is introduced to the semiconductor layer 53 is set using the dose amount and the opening width of the ion implantation mask 65 in the ion implantation.

As shown in FIG. 5D, for example, phosphorus which is the n-type impurity is ion-implanted selectively into the semiconductor layer 53. The portions of the semiconductor layer 53 where the n-type impurity is introduced are positioned directly above the portions of the semiconductor layer 51 where the n-type impurity is introduced. The n-type impurity amount that is introduced to the semiconductor layer 53 is set using the dose and the opening width of an ion implantation mask 67 in the ion implantation.

Similarly to the description recited above, as shown in FIG. 6A, an undoped semiconductor layer 55 and an undoped semiconductor layer 57 are epitaxially grown; and ion implantation into these layers is repeated. Thereby, a stacked body 20f can be formed in which the portions including the p-type impurity are arranged in the Z-direction; and the portions including the n-type impurity are arranged in the Z-direction.

As shown in FIG. 6B, the n-type semiconductor layers 23 and the p-type semiconductor layers 25 are formed by using heat treatment to diffuse the ion-implanted p-type impurity and n-type impurity. The n-type semiconductor layer 23 includes the first portion 23A, the second portion 23B, the third portion 23C, and the fourth portion 23D at levels corresponding respectively to the semiconductor layers 51, 53, 55, and 57. The p-type semiconductor layer 25 includes the fifth portion 25A, the sixth portion 25B, the seventh portion 25C, and the eighth portion 25D at levels corresponding respectively to the semiconductor layers 51, 53, 55, and 57. In FIG. 6B, the semiconductor layers 51, 53, 55, and 57 are shown as one semiconductor layer joined together without discriminating.

In the n-type semiconductor layer 23 and the p-type semiconductor layer 25 formed in such processes, the impurity amounts included in the first to fourth portions 23A to 23D and the fifth to eighth portions 25A to 25D each can be controlled using the dose of the ion implantation and the opening width of the ion implantation mask. Thereby, the impurity profiles shown in FIG. 2B, FIG. 3B, and FIG. 4A can be realized. Also, in the case where the n-type impurity and the p-type impurity are ion-implanted into undoped semiconductor layers, the impurity amount included in each portion is substantially the same as the amount of the ion implanted impurity.

The embodiments recited above are examples; and the embodiments of the invention are not limited thereto. For example, it is unnecessary for the concentration distribution of the n-type semiconductor layer 23 in the active region to be constant; and it is sufficient for the amount of the n-type impurity included in the first portion 23A to be more than the amount of the p-type impurity included in the fifth portion 25A, for the amount of the n-type impurity included in the second portion 23B to be more than the amount of the p-type impurity included in the sixth portion 25B, for the amount of the n-type impurity included in the third portion 23C to be less than the amount of the p-type impurity included in the seventh portion 25C, and for the amount of the n-type impurity included in the fourth portion 23D to be less than the amount of the p-type impurity included in the eighth portion 25D. Also, it is sufficient for the n-type impurity and the p-type impurity to be totally balanced in the active region such that the total amount of n-type impurities and the total amount of p-type impurities are balanced in a region that includes an n-type semiconductor layer 23 and a p-type semiconductor layer 25 adjacent thereto.

The number of semiconductor layers stacked on the semiconductor substrate SS is not limited to four; and the stacked body 20f may include five or more semiconductor layers. In such a case, the n-type semiconductor layer 23 and the p-type semiconductor layer 25 that are disposed in the terminal portion are formed so that the large/small relationship of the n-type impurity amount and the p-type impurity amount reverses alternately in the Z-direction between the portions positioned at the same level among the multiple portions arranged in the Z-direction. On the other hand, the n-type semiconductor layer 23 and the p-type semiconductor layer 25 that are disposed in the active region are formed so that the large/small relationship of the n-type impurity amount and the p-type impurity amount reverses at the center level of the p-type semiconductor layer 25 in the Z-direction.

The n-type semiconductor layer 23 is provided so that, for example, the higher-positioned portions include the same amount of the n-type impurity as the lower-positioned portions or include more of the n-type impurity than the lower-positioned portions. Also, the p-type semiconductor layer 25 is provided so that, for example, the higher-positioned portions include the same amount of the p-type impurity as the lower-positioned portions or include more of the p-type impurity than the lower-positioned portions.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a semiconductor body including a first semiconductor layer of a first conductivity type and a second semiconductor layer of a second conductivity type;
a first electrode provided on a front surface of the semiconductor body;
a second electrode provided on a back surface of the semiconductor body; and
a control electrode provided between the semiconductor body and the first electrode,
the first semiconductor layer and the second semiconductor layer being arranged alternately in a first direction, the first direction being directed along the front surface of the semiconductor body,
the semiconductor body including an active region and a terminal region, the active region including a third semiconductor layer of the second conductivity type and a fourth semiconductor layer of the first conductivity type, the third semiconductor layer being provided between the second semiconductor layer and the first electrode, the fourth semiconductor layer being provided between the third semiconductor layer and the first electrode, the terminal region surrounding the active region and being positioned in a direction along the front surface when viewed from the active region,
the third semiconductor layer and the fourth semiconductor layer not being provided in the terminal region,
the first semiconductor layer including a first portion, a second portion, a third portion, and a fourth portion arranged in a second direction directed from the back surface toward the front surface of the semiconductor body,
the second semiconductor layer including a fifth portion, a sixth portion, a seventh portion, and an eighth portion arranged in the second direction,
the first portion being positioned at the same level as the fifth portion in the second direction, the second portion being positioned at the same level as the sixth portion in the second direction, the third portion being positioned at the same level as the seventh portion in the second direction, the fourth portion being positioned at the same level as the eighth portion in the second direction,
in the first semiconductor layer and the second semiconductor layer positioned in the active region, a second-conductivity-type impurity included in the fifth portion being less than a first-conductivity-type impurity of the first portion, the second-conductivity-type impurity included in the sixth portion being less than the first-conductivity-type impurity of the second portion, the second-conductivity-type impurity included in the seventh portion being more than the first-conductivity-type impurity of the third portion, the second-conductivity-type impurity included in the eighth portion being more than the first-conductivity-type impurity of the fourth portion,
in the first semiconductor layer and the second semiconductor layer positioned in the terminal region, the second-conductivity-type impurity included in the fifth portion being less than the first-conductivity-type impurity of the first portion, the second-conductivity-type impurity included in the sixth portion being more than the first-conductivity-type impurity of the second portion, the second-conductivity-type impurity included in the seventh portion being less than the first-conductivity-type impurity of the third portion, the second-conductivity-type impurity included in the eighth portion being more than the first-conductivity-type impurity of the fourth portion,
in the first semiconductor layer and the second semiconductor layer positioned in the terminal region, a total amount of the first-conductivity-type impurity in the first portion and the second portion being less than a total amount of the first-conductivity-type impurity in the third portion and the fourth portion.

2. The device according to claim 1, wherein the control electrode is positioned on the active region and is disposed to face a portion of the third semiconductor layer with an insulating film interposed.

3. The device according to claim 1, wherein a total amount of the first-conductivity-type impurity and a total amount of the second-conductivity-type impurity are balanced in a region that includes one of mutually-adjacent second semiconductor layers disposed in the active region and a portion of the first semiconductor layer positioned between the mutually-adjacent second semiconductor layers.

4. The device according to claim 1, wherein the first semiconductor layer and the second semiconductor layer are configured in the terminal region such that a total amount of the first conductivity type impurity and a total amount of the second conductivity type impurity are balanced in a region that includes the first portion, the second portion, the fifth portion, and the sixth portion.

5. The device according to claim 1, further comprising a dielectric film provided on the terminal region of the semiconductor body,
the first semiconductor layer and the second semiconductor layer being configured in the terminal region such that the fourth portion and the eighth portion directly contact the dielectric film, and a total amount of the second-conductivity-type impurity is more than a total amount of the first-conductivity-type impurity in a region that includes the third portion, the fourth portion, the seventh portion, and the eighth portion.

6. The device according to claim 5, wherein the first semiconductor layer and the second semiconductor layer are configured in the terminal region such that a difference between a second conductivity type impurity amount of the eighth portion and a first conductivity type impurity amount of the fourth portion is larger than a difference between a first conductivity type impurity amount of the third portion and a second-conductivity-type impurity amount of the seventh portion.

7. The device according to claim 1, wherein the first semiconductor layer is configured in the active region such that first conductivity type impurity amounts included in the first portion, the second portion, the third portion, and the fourth portion are substantially the same.

8. The device according to claim 1, wherein the second semiconductor layer is configured in the active region such that a second conductivity type impurity amount in the fifth portion is substantially the same as a second-conductivity-type impurity amount in the sixth portion, and a second conductivity type impurity amount included in the seventh portion is substantially the same as a second-conductivity-type impurity amount included in the eighth portion.

9. The device according to claim 1, wherein the first semiconductor layer and the second semiconductor layer are configured in the active region such that a large/small relationship between a first conductivity type impurity amount in a portion of the first semiconductor layer and a second conductivity type impurity amount in a portion of the second semiconductor layer reverses at a center of the second semiconductor layer in the second direction, the portion of the second semiconductor layer being positioned at the same level as the portion of the first semiconductor layer in the Z direction.

10. The device according to claim 1, wherein the first semiconductor layer is configured in the terminal region such that first conductivity type impurity amounts included in the third portion and the fourth portion, respectively, are more than the first type impurity amounts included in the first portion and the second portion, respectively.

11. The device according to claim 1, wherein the first semiconductor layer and the second semiconductor layer are configured in the terminal region such that a second conductivity type impurity amount in the sixth portion is more than a second conductivity type impurity amount in the fifth portion; a second conductivity type impurity amount in the seventh portion is more than the second conductivity type impurity amount in the sixth portion; and a second conductivity type impurity amount in the eighth portion is more than the second-conductivity-type impurity amount in the seventh portion.

12. The device according to claim 1, wherein
the semiconductor body further includes a fifth semiconductor layer of the first conductivity type positioned between the first semiconductor layer and the second electrode and between the second semiconductor layer and the second electrode, the fifth semiconductor layer including a first conductivity type impurity having a higher concentration than a concentration of the first conductivity type impurity in the first semiconductor layer, and
the second electrode is electrically connected to the fifth semiconductor layer.

13. The device according to claim 12, wherein the semiconductor body further includes a sixth semiconductor layer of the first conductivity type positioned between the first semiconductor layer and the fifth semiconductor layer and between the second semiconductor layer and the fifth semiconductor layer, the sixth semiconductor layer including a first conductivity type impurity having a lower concentration than a concentration of the first conductivity type impurity in the first semiconductor layer.

14. The device according to claim 1, wherein
the semiconductor body further includes a seventh semiconductor layer of the second conductivity type positioned at a boundary between the active region and the terminal region, and provided between the second semiconductor layer and the first electrode, and
the fourth semiconductor layer is not provided between the seventh semiconductor layer and the first electrode.
